(19) United States
(12) Patent Application Publication
(10) Pub. No.: US 2026/0343870 A1
(43) Pub. Date: Oct. 29, 2026

(54) SEMICONDUCTOR DEVICE AND MANUFACTURING METHOD OF THE SAME

(71) Applicant: SK hynix Inc., Gyeonggi-do (KR)

(72) Inventors: Heon Yong CHANG, Gyeonggi-do (KR); Jong Won BAEK, Gyeonggi-do (KR)

(21) Appl. No.: 19/310,932

(22) Filed: Aug. 27, 2025

(30) Foreign Application Priority Data
Apr. 23, 2025 (KR) 10-2025-0053108

(51) Int. Cl. H10B 12/00

(52) U.S. Cl. CPC H10B 12/50; H10B 12/09; H10B 12/315

(57) ABSTRACT

A semiconductor device is provided. The semiconductor device includes a substrate including a cell region and a peripheral region; a first contact disposed in the peripheral region; a first interlayer dielectric layer disposed on the first contact; a via electrode, disposed in the peripheral region, penetrating the first interlayer dielectric layer and the substrate; and a second interlayer dielectric layer disposed on the first interlayer dielectric layer and covering a side surface and an upper surface of the via electrode.

### CROSS-REFERENCE TO RELATED APPLICATIONS

The present application claims priority under 35 U.S.C. 119(a) to Korean patent application number 10-2025-0053108 filed on Apr. 23, 2025, which is incorporated herein by reference in its entirety.

### BACKGROUND

### 1. Technical Field

Embodiments of the present disclosure relate to a controller and a storage device.

### 2. Related Art

As semiconductor devices become increasingly integrated, the spacing between wirings included in the semiconductor devices has been decreasing. As the spacing between wirings decreases, interference phenomena (e.g., short circuits or parasitic capacitance) may occur between adjacent wirings. Such interference phenomena may adversely affect process stability and device reliability. Therefore, technical solutions to control these phenomena are becoming increasingly important.

### SUMMARY

Embodiments of the present disclosure may provide a semiconductor device and a method of manufacturing the same that can minimize interference between adjacent wirings.

Embodiments of the present disclosure may provide a semiconductor device including a substrate having a cell region and a peripheral region. The semiconductor device may include: a first contact disposed in the peripheral region; a first interlayer dielectric layer disposed on the first contact; a via electrode, disposed in the peripheral region, penetrating at least a portion of the substrate and the first interlayer dielectric layer; and a second interlayer dielectric layer disposed on the first interlayer dielectric layer and covering a side surface and an upper surface of the via electrode.

Embodiments of the present disclosure may provide a semiconductor device including: a substrate including a cell region and a peripheral region; a first contact disposed on the substrate; a first interlayer dielectric layer disposed on the first contact; a via electrode penetrating at least a portion of the substrate and having an upper surface positioned higher than an upper surface of the first contact; and a second interlayer dielectric layer surrounding at least a portion of a side surface of the via electrode and spaced apart from the first contact.

Embodiments of the present disclosure may also provide a method of manufacturing a semiconductor device. The method may include: forming a first contact on a substrate; forming a first interlayer dielectric layer covering the first contact; forming a first nitride layer on the first interlayer dielectric layer; forming a via electrode penetrating the first interlayer dielectric layer and at least a portion of the nitride layer; removing a remaining portion of the first nitride layer; and forming a second interlayer dielectric layer on the first interlayer dielectric layer such that the second interlayer dielectric layer contacts an upper surface and a side surface of the via electrode.

According to embodiments of the present disclosure, interference between adjacent wirings can be minimized.

The effects of the embodiments of the present disclosure are not limited to those described above, and additional effects not mentioned will be clearly understood by those skilled in the art based on the appended claims.

### BRIEF DESCRIPTION OF THE DRAWINGS

The present disclosure will be more fully understood from the following detailed description and the accompanying drawings, which are provided solely for illustrative purposes and are not intended to limit the scope of the present disclosure.

FIG. 1 is a cross-sectional view illustrating an example of a semiconductor device according to an embodiment of the present disclosure.

FIG. 2 is an enlarged view of a region 140 in FIG. 1.

FIGS. 3 - FIG 11 are cross-sectional views for describing a method of manufacturing a semiconductor device according to embodiments of the present disclosure.

FIG. 12 is a cross-sectional view of a semiconductor device according to another embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or similar components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, but is used merely to distinguish the corresponding element from other elements.

When it is mentioned that a first element "is connected or coupled to", “contacts or overlaps” etc., a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc., each other via a fourth element. Here, the second element may be included in at least one of two or more elements that "are connected or coupled to", “contact or overlap”, etc., each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc., are mentioned, it should be considered that numerical values for an elements or features, or corresponding information (e.g., level, range, etc.) include a tolerance or error range that may be caused by various factors (e.g., process factors, internal or external impact, noise) even when a relevant description is not specified. Further, the term “may” fully encompasses all the meanings of the term “can”.

Hereinafter, various embodiments of the present disclosure will be described in detail with reference to accompanying drawings.

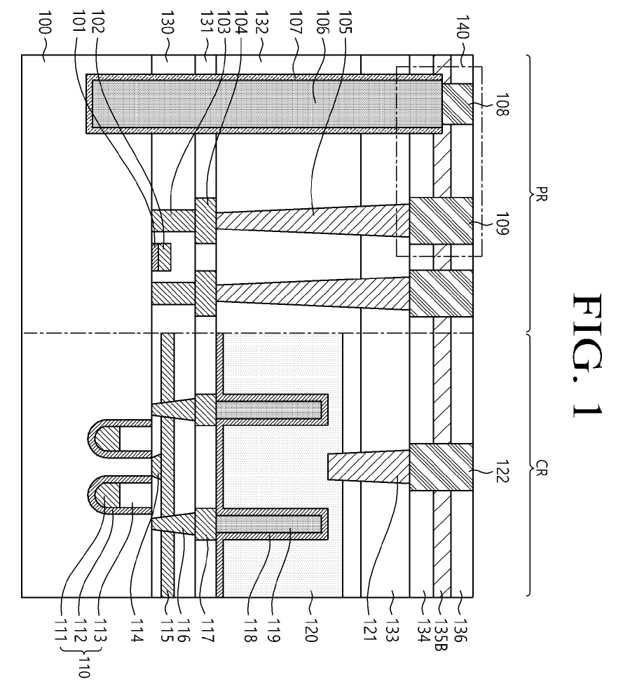

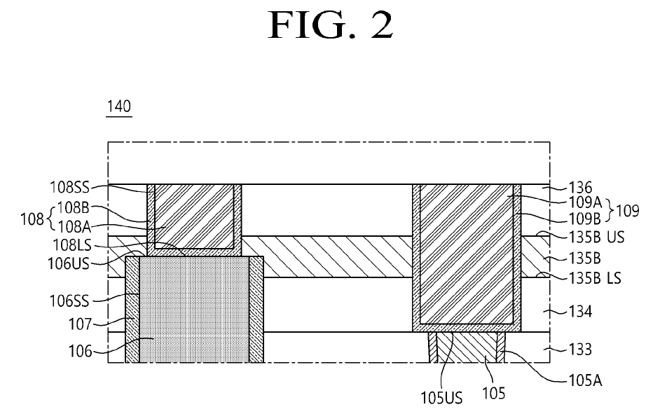

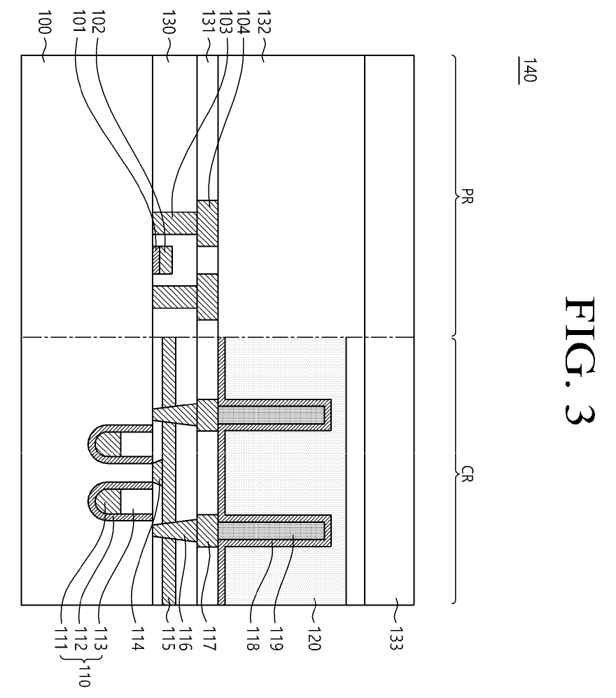

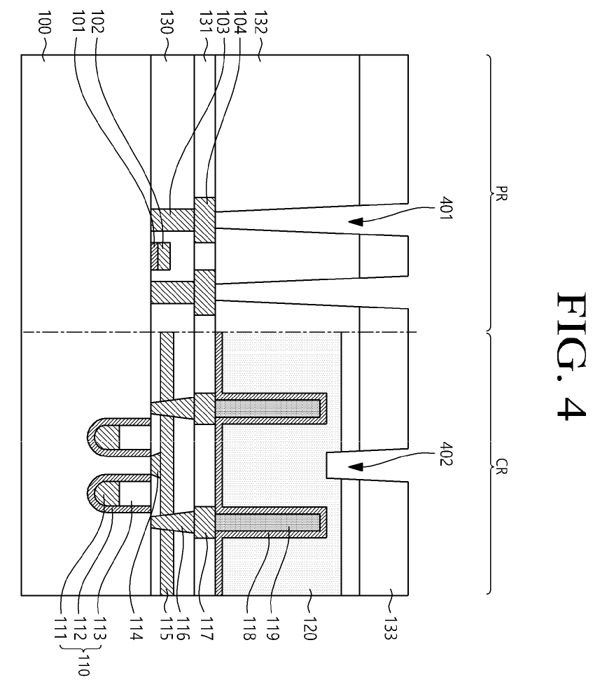

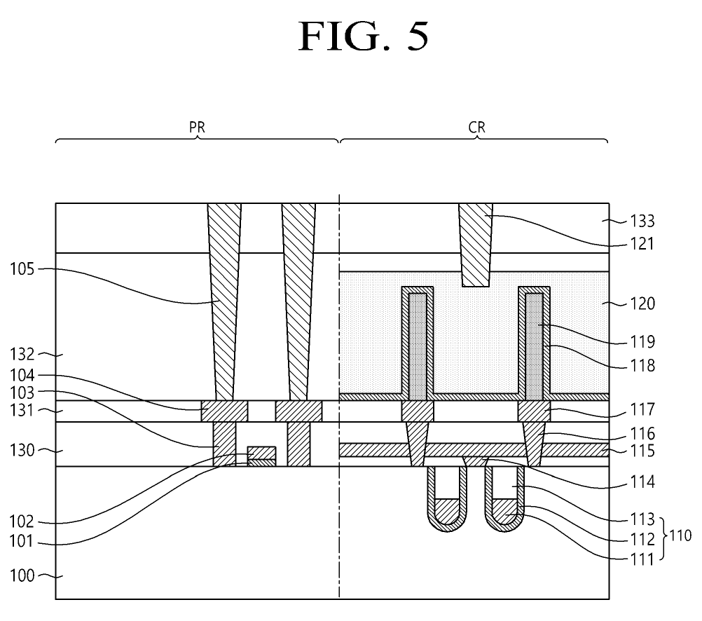

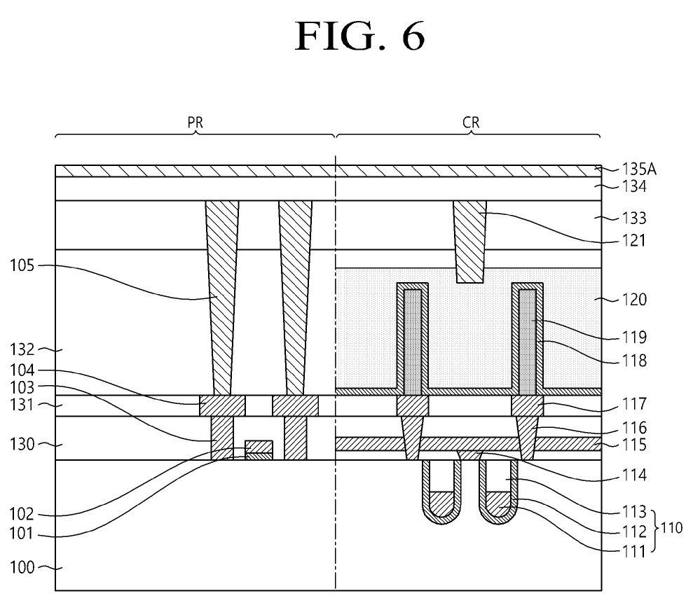

FIG. 1 is a cross-sectional view illustrating a semiconductor device according to an embodiment of the present disclosure. FIG. 2 is an enlarged view of region 140 in FIG. 1.

Referring to FIGS. 1 and FIG. 2 , the semiconductor device may include a substrate 100, a gate insulating layer 101, a gate 102, a lower contact plug 103, a lower wiring 104, a first contact 105, a via electrode 106, a via electrode barrier layer 107, a first wiring 108, a second wiring 109, a gate structure 110, a bit line contact 114, a bit line 115, a contact plug 116, a landing pad 117, a dielectric layer 118, a first electrode 119, a second electrode 120, a second contact 121, a third wiring 122, a separation insulating layer 130, a first capping layer 131, a second capping layer 132, a third capping layer 133, a first interlayer dielectric layer 134, a second interlayer dielectric layer 135B, and a third interlayer dielectric layer 136.

The substrate 100 (or the gate structure 110) may include a semiconductor substrate such as a silicon wafer or a silicon-on-insulator (SOI) wafer. The substrate 100 may also include a Group III-V compound semiconductor substrate, for example, a gallium arsenide (GaAs) substrate. The substrate 100 may include single-crystal silicon, polysilicon, amorphous silicon, monocrystalline silicon-germanium, polycrystalline silicon-germanium, carbon-doped silicon, or a combination thereof.

Although not illustrated, the substrate 100 may include at least one device isolation layer in a cell region CR and a peripheral region PR. The device isolation layer may be formed using a trench-type isolation technique, such as shallow trench isolation (STI). The device isolation layer may include silicon oxide, silicon nitride, silicon oxynitride, low-k dielectric, high-k dielectric, or a combination thereof.

In the cell region CR, the gate structure 110 may include a word line 111, a gate insulating layer 112, and a gate capping layer 113. An upper surface of the word line 111 may be located lower than an upper surface of the substrate 100. The word line 111 may be a buried gate or a buried word line. The gate capping layer 113 may be disposed on the word line 111. The gate insulating layer 112 may surround sidewalls of the word line 111 and the gate capping layer 113.

The word line 111 may include a conductive material such as a metal, metal oxide, metal nitride, metal silicide, polysilicon, conductive carbon, or a combination thereof. The gate capping layer 113 may include silicon oxide, silicon nitride, silicon oxynitride, a low-k dielectric, a high-k dielectric, or a combination thereof. In some embodiments, the gate capping layer 113 may include a high dielectric constant (high-k) material.

The separation insulating layer 130, the lower contact plug 103, the gate insulating layer 101, the gate 102, the bit line contact 114, and the contact plug 116 may be disposed on the substrate 100.

In the cell region CR, the bit line 115 may be disposed on the bit line contact 114. The bit line 115 may be arranged in a direction perpendicular to the word line 111. The bit line 115 may not be in contact with the contact plug 116. In other words, although not illustrated, an insulating layer may be disposed between the bit line 115 and the contact plug 116. The landing pads 117 and the first capping layer 131 may be disposed on the contact plug 116. The landing pads 117 may vertically overlap the contact plugs 116.

In the peripheral region PR, the lower contact plugs 103 and the gate 102 may be disposed on the substrate 100. The lower wirings 104 and the first capping layer 131 may be disposed on the lower contact plugs 103. The lower wirings 104 may vertically overlap the lower contact plugs 103. In one embodiment, the lower contact plugs 103 and the gate 102 may serve as source/drain electrodes and gate electrodes, respectively, of transistors included in various circuits of the peripheral region PR.

In the peripheral region PR, the via electrode 106 may penetrate the separation insulating layer 130, the first capping layer 131, the second capping layer 132, the third capping layer 133, and the first interlayer dielectric layer 134. The via electrode 106 may extend into the substrate 100.

The via electrode barrier layer 107 may be disposed on a side surface 106SS of the via electrode 106. The via electrode barrier layer 107 may include a metal, metal nitride, or a combination thereof such as tantalum (Ta), tantalum nitride (TaN), titanium (Ti), titanium nitride (TiN), ruthenium (Ru), cobalt (Co), nickel (Ni), nickel-boron alloy (NiB), and tungsten nitride (WN).

The via electrode 106 may include copper (Cu), manganese (Mn), aluminum (Al), gold (Au), indium (In), nickel (Ni), or a combination thereof.

A distance from the upper surface 106US of the via electrode 106 to the upper surface of the substrate 100 may be greater than a distance from the upper surface 105US of the first contact 105 to the upper surface of the substrate 100. The upper surface 106US of the via electrode 106 may be located within the second interlayer dielectric layer 135B.

The second interlayer dielectric layer 135B may surround the upper surface 106USof the via electrode 106 and at least a portion of its side surface 106SS. The second interlayer dielectric layer 135B may be in contact with the upper surface 106US of the via electrode 106.

The first contact 105 in the peripheral region PR may penetrate the second capping layer 132 and the third capping layer 133. The first contact 105 may be electrically connected to the lower wiring 104. The first contact 105 may be made of a conductive material.

The second contact 121 in the cell region CR may penetrate the second capping layer 132 and the third capping layer 133. The second contact 121 may be electrically connected to the second electrode 120. The second contact 121 may be made of a conductive material. An upper surface of the second contact 121 may be coplanar with a lower surface of the third wiring 122. The upper surface of the second contact 121 may be in contact with a lower surface of the first interlayer dielectric layer 134.

In one example, the second contact 121 may include a barrier layer. The second contact 121 may include a conductive material such as copper (Cu) or copper-manganese (CuMn). The upper surface of the second contact 121 may be coplanar with the upper surface 105US of the first contact 105.

The first wiring 108 disposed in the peripheral region PR may penetrate the second interlayer dielectric layer 135B and the third interlayer dielectric layer 136. The first wiring 108 may be electrically connected to the via electrode 106.

In the peripheral region PR, the second wiring 109 may penetrate the first interlayer dielectric layer 134, the second interlayer dielectric layer 135B, and the third interlayer dielectric layer 136. The second wiring 109 may be electrically connected to the first contact 105.

In the cell region CR, the third wiring 122 may penetrate the first interlayer dielectric layer 134, the second interlayer dielectric layer 135B, and the third interlayer dielectric layer 136. The third wiring 122 may be electrically connected to the second contact 121. The second wiring 109 and the third wiring 122 may include the same material as the first wiring 108.

The first wiring 108 may be in contact with the via electrode 106. The second wiring 109 may cover the upper surface of the first contact 105. The third wiring 122 may cover the upper surface of the second contact 121. A thickness of the first wiring 108 may be less than a thickness of the second wiring 109 and the third wiring 122.

A distance from a lower surface 108LS of the first wiring 108 to the upper surface of the substrate 100 may be greater than a distance from a lower surface of the second wiring 109 to the upper surface of the substrate 100. The distance from the lower surface of the second wiring 109 to the substrate 100 may be equal to the distance from the lower surface of the third wiring 122 to the substrate 100. Upper surfaces of the first wiring 108, the second wiring 109, and the third wiring 122 may be coplanar.

The first interlayer dielectric layer 134 and the third interlayer dielectric layer 136 may include an oxide such as Boro-phospho-silicate glass (BPSG), Phospho-silicate glass (PSG), Spin-on-glass (SOG), Tetraethyl orthosilicate (TEOS), or High Density Plasma (HDP). The first capping layer 131, the second capping layer 132, and the third capping layer 133 may also include the same material as the first and third interlayer dielectric layers 134 and 136.

The second interlayer dielectric layer 135B may include a material different from that of the first interlayer dielectric layer 134 and the third interlayer dielectric layer 136. For example, the second interlayer dielectric layer 135B may include a nitride.

The second interlayer dielectric layer 135B may surround a side surface 106SS of the via electrode 106. The second interlayer dielectric layer 135B may be spaced apart from the first contact 105. In one embodiment, An insulating layer may be present between the second interlayer dielectric layer 135B and the first contact 105. In one embodiment, the insulating layer may include an oxide.

The bit line contact 114, the bit line 115, the contact plug 116, the landing pad 117, the lower contact plug 103, the gate 102, and the lower wiring 104 may include a conductive material such as a metal, metal oxide, metal nitride, metal silicide, polysilicon, conductive carbon, or a combination thereof.

In the cell region CR, the first electrode 119, the dielectric layer 118, and the second electrode 120 may be disposed on the first capping layer 131 and the landing pad 117. The first electrode 119, the dielectric layer 118, and the second electrode 120 may constitute a capacitor of a memory cell. Although not shown, an etch stop layer may be further disposed between the first capping layer 131 and the dielectric layer 118.

The first electrode 119 may vertically overlap the landing pad 117. Although not illustrated, a support pattern layer may be disposed on a side surface of the first electrode 119. The support pattern layer may surround the side surface of the first electrode 119. The support pattern layer disposed on one first electrode 119 may be separated from the support pattern layer disposed on a side surface of another first electrode 119.

The dielectric layer 118 may be disposed to cover the surface of the first electrode 119 and the support pattern layer. The second electrode 120 may be disposed on the dielectric layer 118. An upper surface of the second electrode 120 may be higher than an upper surface of the first electrode 119.

The first electrode 119 and the second electrode 120 may include a conductive material such as a metal, metal oxide, metal nitride, metal silicide, polysilicon, conductive carbon, or a combination thereof. The dielectric layer 118 may include a high dielectric constant (high-k) material such as silicon oxide, silicon nitride, or a combination thereof.

Referring to FIG. 2, the first wiring 108 may include a first wiring conductive layer 108A and a first wiring barrier portion 108B. The first wiring barrier portion 108B may surround a lower surface and side surfaces of the first wiring conductive layer 108A.

The first wiring barrier portion 108B may include a conductive material such as copper (Cu), tungsten (W), tantalum nitride (TaN), or a combination thereof. In one embodiment, the first wiring conductive layer 108A may include a conductive material such as copper (Cu), manganese (Mn), or the like.

The lower surface 108LS of the first wiring 108 may be located in the second interlayer dielectric layer 135B. The lower surface 108LS of the first wiring 108 may be lower than the upper surface 135B US of the second interlayer dielectric layer 135B. The lower surface 108LS of the first wiring 108 may be higher than a lower surface 135B LS of the second interlayer dielectric layer 135B.

The lower surface 108LS of the first wiring 108 may be in contact with the upper surface 106US of the via electrode 106. An upper surface of the first wiring 108 may be coplanar with an upper surface of the third interlayer dielectric layer 136.

The second wiring 109 may include a second wiring conductive layer 109A and a second wiring barrier portion 109B. The second wiring barrier portion 109B may surround a lower surface and side surfaces of the second wiring 109.

The second wiring barrier portion 109B may include a conductive material such as copper (Cu), tungsten (W), tantalum nitride (TaN), or a combination thereof. In one embodiment, the second wiring conductive layer 109A may include a conductive material such as copper (Cu), manganese (Mn), or the like.

A lower surface of the second wiring 109 may be in contact with the upper surface 105US of the first contact 105. An upper surface of the second wiring 109 may be coplanar with an upper surface of the third interlayer dielectric layer 136.

The upper surface 105US of the first contact 105 may be coplanar with the lower surface of the second wiring 109. The first contact 105 may include a first contact barrier layer 105A. For example, the first contact barrier layer 105A may include a conductive material such as copper (Cu), tungsten (W), tantalum nitride (TaN), or a combination thereof.

The upper surface 106US of the via electrode 106 may be located between the upper surface 135B US and the lower surface 135B LS of the second interlayer dielectric layer 135B. The second interlayer dielectric layer 135B may be disposed on a side surface 106SS of the via electrode 106.

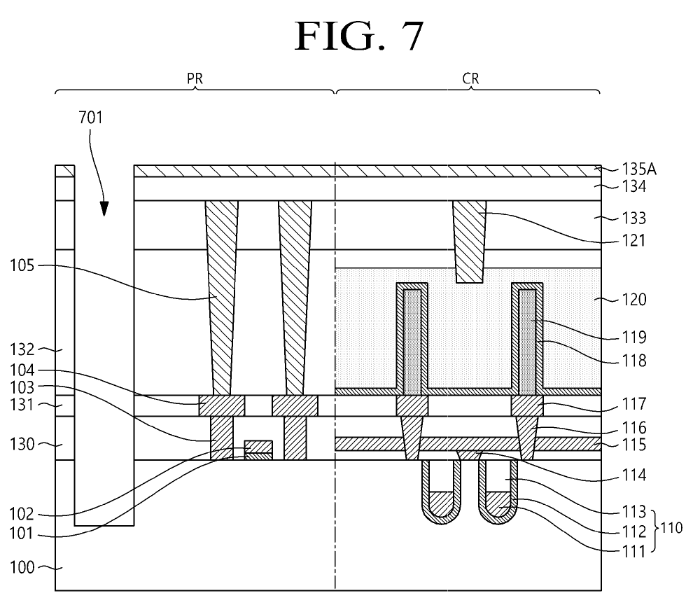

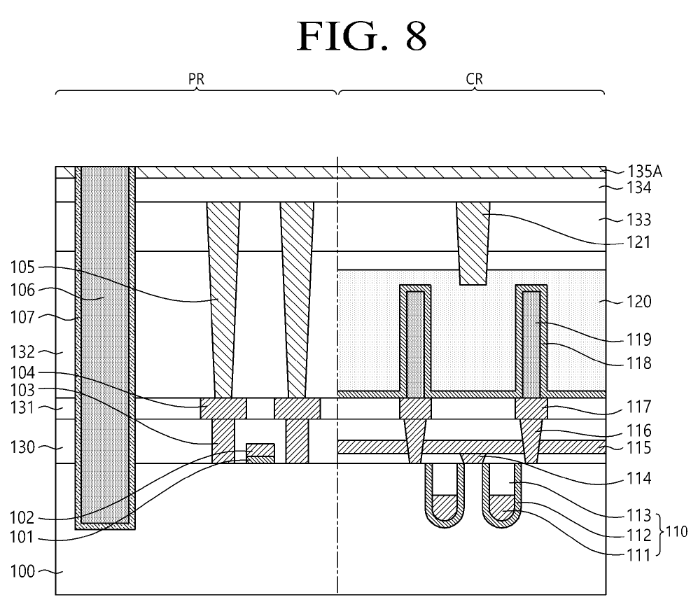

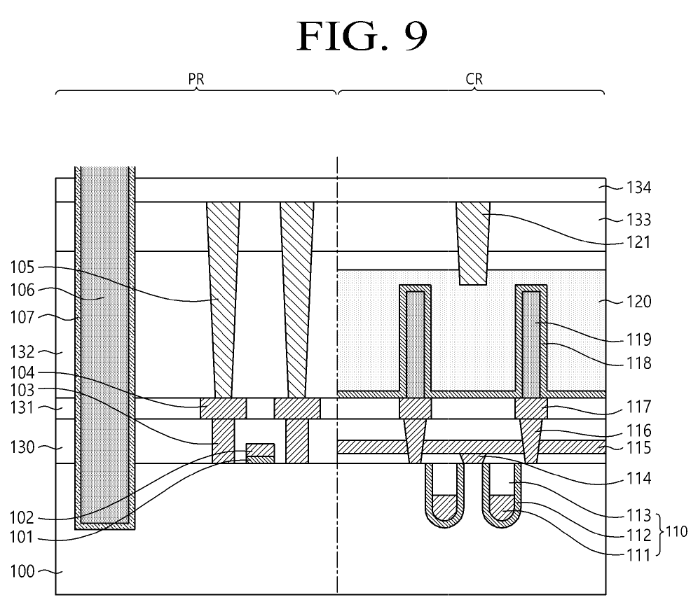

FIGS. 3 through FIG. 11 are cross-sectional views for explaining a method of manufacturing the semiconductor device according to embodiments of the present disclosure.

Referring to FIG. 3, the gate structure 110 may be formed in the cell region CR. The separation insulating layer 130 may be formed on the substrate 100. The bit line contact 114, the bit line 115, and the contact plug 116 may be formed in the separation insulating layer 130. The first capping layer 131 and the landing pad 117 may be formed on the separation insulating layer 130. The second capping layer 132 may be disposed on the first capping layer 131. The first electrode 119, the dielectric layer 118, and the second electrode 120 may be formed on the second capping layer 132.

The gate 102, the gate insulating layer 101, and the lower contact plug 103 may be formed in the separation insulating layer 130 on the substrate 100 in the peripheral region PR. The lower wiring 104 may be formed on the first capping layer 131 on the separation insulating layer 130. The second capping layer 132 may be disposed on the first capping layer 131.

After depositing the second capping layer 132, an upper portion of the second capping layer 132 may be removed by a planarization process. The planarization process may include a chemical mechanical polishing (CMP) process. The third capping layer 133 may be formed on the planarized second capping layer 132. In one embodiment, the third capping layer 133 may include an oxide.

Referring to FIG. 4, contact holes penetrating the second capping layer 132 and the third capping layer 133 may be formed. The contact holes may include a first contact hole 401 formed in the peripheral region PR and a second contact hole 402 formed in the cell region CR. The first contact hole 401 may be in contact with an upper surface of the lower wiring 104. The second contact hole 402 may be connected to the second electrode 120. When the first contact hole 401 is formed, at least a portion of the second capping layer 132 and the third capping layer 133 may be removed.

The first contact hole 401 may be configured to expose at least a portion of the lower wiring 104. The second contact hole 402 may be configured to expose at least a portion of the second electrode 120. A height of the first contact hole 401 formed in the peripheral region PR may be greater than a height of the second contact hole 402 formed in the cell region CR.

Referring to FIG. 5, in the peripheral region PR, the first contact 105 may be formed to fill the first contact hole 401. A lower surface of the first contact 105 may be in contact with the lower wiring 104. The upper surface of the first contact 105 may be in contact with the first interlayer dielectric layer 134 of FIG. 6. A plurality of first contacts 105 may be provided on the substrate 100 of a semiconductor device.

In the cell region CR, the second contact 121 may be formed to fill the second contact hole 402. A lower surface of the second contact 121 may be connected to the second electrode 120. The upper surface of the second contact 121 may be in contact with the first interlayer dielectric layer 134. The upper surface of the first contact 105 and the upper surface of the second contact 121 may be coplanar.

Referring to FIG. 6, the first interlayer dielectric layer 134 is formed on the third capping layer 133. The first interlayer dielectric layer 134 is formed to cover upper portions of the first contact 105 and the second contact 121. The first interlayer dielectric layer 134 may prevent oxidation of the first contact 105 and the second contact 121.

A nitride layer 135A is formed on the first interlayer dielectric layer 134. In one embodiment, the nitride layer 135A may function as a barrier layer during a subsequent via electrode 106 formation process. The nitride layer 135A may include the same material as the second interlayer dielectric layer 135B.

Referring to FIG. 7, a via electrode hole 701 may penetrate the first capping layer 131, the second capping layer 132, the third capping layer 133, the first interlayer dielectric layer 134, and the second interlayer dielectric layer 135B. The via electrode hole 701 may extend into the substrate 100. A via electrode 106 of FIG. 8 may be formed in the via electrode hole 701 by a subsequent process.

When the via electrode hole 701 is formed, at least a portion of the nitride layer 135A in the corresponding region may be removed, and at least a portion of the substrate 100 may also be removed. The via electrode hole 701 may be formed by an exposure and etching process.

Referring to FIG. 8, the via electrode barrier layer 107 may be formed inside the via electrode hole 701. The via electrode barrier layer 107 may include tantalum (Ta), tantalum nitride (TaN), titanium (Ti), titanium nitride (TiN), ruthenium (Ru), cobalt (Co), nickel (Ni), nickel boron alloy (NiB), or tungsten nitride (WN) or a combination thereof.

After forming the via electrode barrier layer 107, a conductive material may be deposited therein to form the via electrode 106. The via electrode 106 may include copper (Cu), copper manganese (CuMn), or a combination thereof.

Referring to FIG. 9, the nitride layer 135A may be etched to expose the first interlayer dielectric layer 134. By etching the nitride layer 135A, at least a portion of the upper surface and the side surface of the via electrode 106 may be exposed. The etching process may include a chemical mechanical polishing (CMP) process. In a subsequent step, the second interlayer dielectric layer 135B of FIG. 10 may be formed in the region where the nitride layer 135A has been removed.

In one embodiment, the second interlayer dielectric layer 135B may function as an etch stop layer during an etching process for forming a first wiring hole 1101 and a second wiring hole 1102.

Referring to FIG. 10, the second interlayer dielectric layer 135B may be formed on the first interlayer dielectric layer 134. A thickness of the second interlayer dielectric layer 135B may be greater than that of the previously formed nitride layer 135A. The second interlayer dielectric layer 135B surrounds the upper surface of the via electrode 106 and at least a portion of the side surface of the via electrode 106. The second interlayer dielectric layer 135B is formed such that the upper surface of the via electrode 106 is positioned between an upper surface and a lower surface of the second interlayer dielectric layer 135B.

The third interlayer dielectric layer 136 is formed on the second interlayer dielectric layer 135B. The third interlayer dielectric layer 136 may include an oxide such as BPSG, PSG, SOG, TEOS, or HDP.

Referring to FIG. 11, the first wiring hole 1101 may be formed by etching the third interlayer dielectric layer 136. The first wiring hole 1101 may also be formed by etching a portion of the second interlayer dielectric layer 135B to expose a portion of the upper surface of the via electrode 106.

Since a width of the via electrode 106 is greater than a width of the first wiring 108, a portion of the center of the upper surface of the via electrode 106 may be exposed. A side portion of the second interlayer dielectric layer 135B may also be exposed when forming the first wiring hole 1101.

The second wiring hole 1102 may be formed by etching the first interlayer dielectric layer 134, the second interlayer dielectric layer 135B, and the third interlayer dielectric layer 136. When forming the second wiring hole 1102, the upper surface of the first contact 105 may be exposed. A portion of the side surfaces of the first interlayer dielectric layer 134, the second interlayer dielectric layer 135B, and the third interlayer dielectric layer 136 may also be exposed when forming the second wiring hole 1102.

The third wiring hole 1103 may be formed by etching the first interlayer dielectric layer 134, the second interlayer dielectric layer 135B, and the third interlayer dielectric layer 136. When forming the third wiring hole 1103, the upper surface of the second contact 121 may be exposed. A portion of the side surfaces of the first interlayer dielectric layer 134, the second interlayer dielectric layer 135B, and the third interlayer dielectric layer 136 may also be exposed, when forming the third wiring hole 1103.

In one embodiment, the first wiring hole 1101, the second wiring hole 1102, and the third wiring hole 1103 may be formed simultaneously on the via electrode 106, the first contact 105, and the second contact 121, respectively.

Referring again to FIGS. 11 and FIG. 1, barrier portions may be formed along the inner side surfaces and bottom surfaces of the first wiring hole 1101, the second wiring hole 1102, and the third wiring hole 1103. Then, conductive material may be deposited into the first wiring hole 1101, the second wiring hole 1102, and the third wiring hole 1103 to form the first wiring 108, the second wiring 109, and the third wiring 122, respectively.

The surfaces of the first wiring 108, the second wiring 109, and the third wiring 122 may be planarized. The planarization process may include a chemical mechanical polishing (CMP) process.

The barrier portions of the first wiring 108, the second wiring 109, and the third wiring 122 may include copper (Cu), tungsten (W), tantalum (Ta), tantalum nitride (TaN), titanium nitride (TiN), or a combination thereof. A conductive material such as copper or tungsten may be deposited inside the first wiring 108, the second wiring 109, and the third wiring 122.

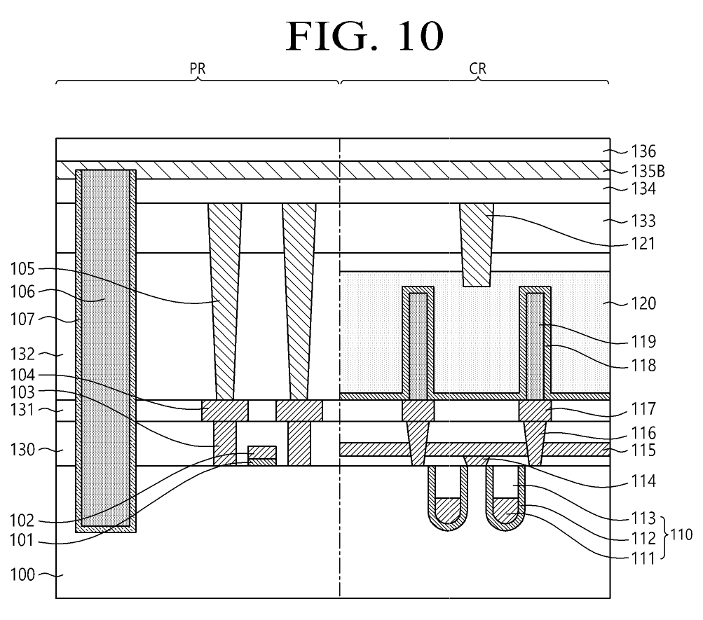

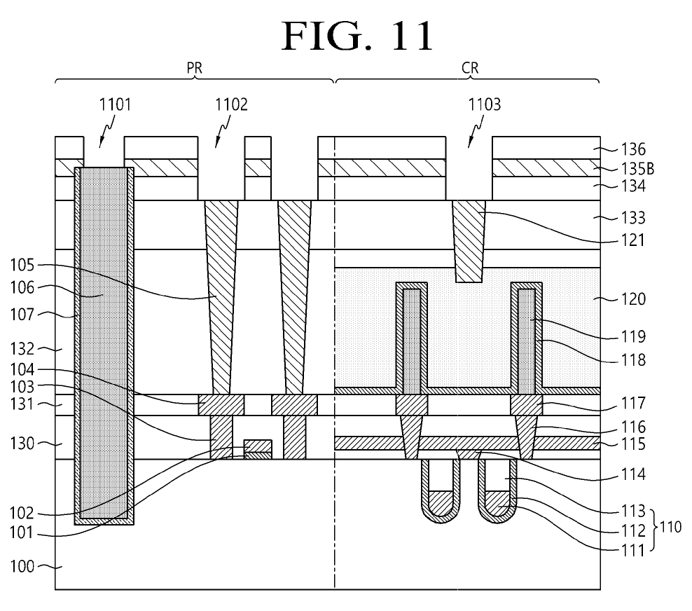

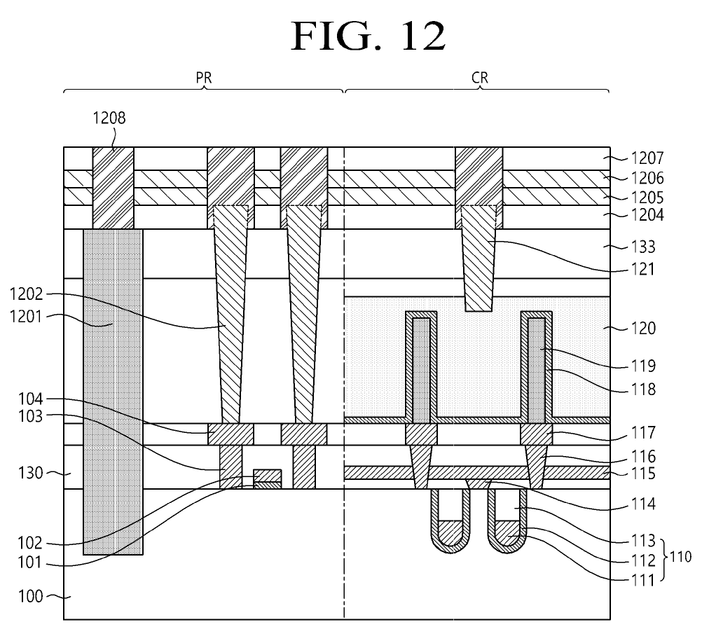

FIG. 12 is a cross-sectional view illustrating another embodiment of the present disclosure. The embodiment described herein below is a different embodiment to the embodiments described above in the present disclosure.

Referring to FIG. 12, in a different embodiment from those previously described with respect to FIGS. 1 -11 in the present disclosure, a first nitride layer 1205 is formed after forming the via electrode 1201, followed by formation of the first contact 1202 and then a second nitride layer 1206. As a result, a plurality of nitride layers is formed between wirings 1208. If a plurality of nitride layers is formed between adjacent wirings 1208, compressive stress may be generated between the nitride layers, and copper migration may occur during the etching process of the wirings 1208 at weak adhesion interfaces between the nitride layers.

According to embodiments of the present disclosure, since the nitride layer 135A formed on an upper portion of the via electrode 106 is removed and the second interlayer dielectric layer 135B is then formed, only a single nitride layer is formed between the first wiring 108, the second wiring 109, and the third wiring 122. Accordingly, since no nitride layer interface is present between the first wiring 108, the second wiring 109, and the third wiring 122, process defects due to copper migration can be prevented.

Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A semiconductor device comprising:
a substrate including a cell region and a peripheral region;
a first contact disposed in the peripheral region;
a first interlayer dielectric layer disposed on the first contact;
a via electrode, disposed in the peripheral region, penetrating the first interlayer dielectric layer and at least a portion of the substrate; and
a second interlayer dielectric layer disposed on the first interlayer dielectric layer and covering a side surface and an upper surface of the via electrode.

2. The semiconductor device according to claim 1,
wherein the upper surface of the via electrode is higher than an upper surface of the first contact.

3. The semiconductor device according to claim 1, further comprising:
a first wiring connected to the via electrode; and
a second wiring disposed on the first contact,
wherein a lower surface of the first wiring is disposed inside the second interlayer dielectric layer.

4. The semiconductor device according to claim 3,
wherein a thickness of the first wiring is less than a thickness of the second wiring.

5. The semiconductor device according to claim 3,
wherein the second wiring penetrates the second interlayer dielectric layer and the first interlayer dielectric layer.

6. The semiconductor device according to claim 3,
wherein the first wiring and the second wiring include copper, tungsten, tantalum, tantalum nitride, titanium nitride, or a combination thereof.

7. The semiconductor device according to claim 3,
wherein the second wiring covers the upper surface of the first contact.

8. The semiconductor device according to claim 3,
wherein the second interlayer dielectric layer is disposed on a side surface of the first wiring.

9. The semiconductor device according to claim 1,
wherein the second interlayer dielectric layer is disposed in contact with the upper surface of the via electrode.

10. The semiconductor device according to claim 1,
wherein the first interlayer dielectric layer includes an oxide, and the second interlayer dielectric layer includes a nitride.

11. The semiconductor device according to claim 1, further comprising:
a first electrode disposed in the cell region;
a second electrode disposed on the first electrode;
a dielectric layer disposed between the first electrode and the second electrode; and
a second contact connected to the second electrode,
wherein an upper surface of the second contact is coplanar with an upper surface of the first contact.

12. A semiconductor device comprising:
a substrate;
a first contact disposed on the substrate;
a first interlayer dielectric layer disposed on the first contact;
a via electrode penetrating at least a portion of the substrate and having an upper surface higher than an upper surface of the first contact; and
a second interlayer dielectric layer surrounding at least a portion of a side surface of the via electrode and spaced apart from the first contact.

13. The semiconductor device according to claim 12,
wherein the upper surface of the via electrode is disposed between a top surface and a bottom surface of the second interlayer dielectric layer.

14. The semiconductor device according to claim 12,
wherein the second interlayer dielectric layer is disposed in contact with the upper surface of the via electrode.

15. The semiconductor device according to claim 12,
further comprising a first wiring connected to the via electrode,
wherein the second interlayer dielectric layer is disposed on a side surface of the first wiring.

16. The semiconductor device according to claim 15,
further comprising a second wiring connected to the first contact,
wherein a thickness of the second wiring is greater than a thickness of the first wiring.

17. A method of manufacturing a semiconductor device, the method comprising:
forming a first contact on a substrate;
forming a first interlayer dielectric layer covering the first contact;
forming a nitride layer on the first interlayer dielectric layer;
forming a via electrode penetrating the first interlayer dielectric layer and at least a portion of the nitride layer;
removing a remaining portion of the nitride layer; and
forming a second interlayer dielectric layer on the first interlayer dielectric layer such that the second interlayer dielectric layer contacts an upper surface and a side surface of the via electrode.

18. The method according to claim 17,
wherein the removing of the remaining portion of the nitride layer includes removing the remaining portion of the nitride layer to expose at least a portion of the upper surface and side surface of the via electrode.

19. The method according to claim 17, further comprising:
forming a first wiring on the first contact and a second wiring on the via electrode.

20. The method according to claim 19, wherein the forming of the first wiring further comprises:
removing at least a portion of the second interlayer dielectric layer to expose the upper surface of the via electrode.
